(19) United States
(12) Patent Application Publication
(10) Pub. No.: US 2012/0042923 A1
(43) Pub. Date: Feb. 23, 2012

(54) Thin Film Solar Cell and Thin Film Solar Cell System

(75) Inventors: Chin-Yao Tsai, Tainan (TW); Chien-Sheng Yang, Tainan (TW)

(73) Assignee: AURIA SOLAR, Tainan (TW)

(21) Appl. No.: 12/967,506

(22) Filed: Dec. 14, 2010

(30) Foreign Application Priority Data
Dec. 14, 2009 (TW) 98142753
Dec. 14, 2009 (TW) 98142754
Dec. 16, 2009 (TW) 98143232

(51) Int. Cl. H01L 31/042

(52) U.S. Cl. 136/244

(57) ABSTRACT

A thin film solar cell includes a substrate, a plurality of photovoltaic cells and at least one control unit. The photovoltaic cells generate a photocurrent respectively. Each photovoltaic cell includes a first conductive layer disposed on the substrate, a photovoltaic layer and a second conductive layer. The photovoltaic layer disposed on the first conductive layer has an opening exposing the first conductive layer. The second conductive layer disposed on the photovoltaic layer is connected electrically to the first conductive layer of the adjacent photovoltaic cell through the opening. The control unit is connected to at least one of the photovoltaic cell electrically. When the photocurrent generated by at least one of the photovoltaic cells is different from the photocurrent generated by other photovoltaic cells, the control unit provided a compensable current to the first photovoltaic cell to make the photocurrents provided by the overall photovoltaic cells being matched.

### CROSS-REFERENCE TO RELATED PATENT APPLICATION

This application claims priority to and the benefit of Taiwan Patent Applications No. TW98142753, filed Dec. 14, 2009, No. TW98142754, filed Dec. 14, 2009, and No. TW98143232, filed Dec. 16, 2009, the contents of which are incorporated herein in their entireties by reference.

### FIELD OF INVENTION

The present invention relates to a thin film solar cell and a manufacturing method thereof, and more particularly to a thin film solar cell with higher photoelectric conversion efficiency and a manufacturing and optimization method thereof.

### BACKGROUND OF THE INVENTION

With the raise of the consciousness of environmental protection, the concept of energy saving and carbon dioxide reduction has gradually drawn attention, and the development and utilization of renewable energy have become the focus in the world. A solar cell which converts solar light into electricity is the most promising in energy industry nowadays, so that manufacturers devote themselves to the manufacturing of the solar cell. Currently, the key issue of the solar cell is the improvement of the photoelectric conversion efficiency thereof. Therefore, to improve the photoelectric conversion efficiency of the solar cell means enhancing the product competitiveness.

Solar cells using monocrystalline silicon or polycrystalline silicon account for more than 90% in the solar cell market. However, these solar cells are made from silicon wafers of 150 μm to 350 μm thick, and the process cost thereof is higher. In addition, the raw materials of solar cells are silicon ingots with high quality. The silicon ingots face the shortage problem as the usage quantity thereof is increased significantly in recent years. Therefore, the thin film solar cell has been the new focus due to the advantages of low cost, easy for large-area production and simple module process, etc.

Generally speaking, in a conventional thin film solar cell, an electrode layer, a photovoltaic layer and another electrode layer are sequentially blanket-stacked on a substrate. During the process of stacking these layers, these layers are patterned by performing laser cutting processes, so as to form a plurality of sub cells connected in series. When a light enters the thin film solar cell from outside, free electron-hole pairs are generated in the photovoltaic layer by the solar energy, and the internal electric field formed by the PN junction makes electrons and holes respectively move toward two layers, so as to generate a storage state of electricity. Meanwhile, if a load circuit or an electronic device is connected, the electricity can be provided to drive the circuit or device.

However, the conventional thin film solar cell still has considerable room to improve the photoelectric conversion efficiency. Thus, how to improve the photoelectric conversion efficiency and performance of a thin film solar cell in order to improve the overall competitiveness of the product become the issues of concern.

### SUMMARY OF THE INVENTION

The present invention provides a thin film solar cell having a higher photoelectric conversion efficiency.

The present invention further provides a thin film solar cell system, in which photo current respectively generated by the plurality of thin film solar cell modules can be current matching and a better photoelectric conversion efficiency can be obtained.

The present invention provides a thin film solar cell including a substrate, a plurality of photovoltaic cells, and at least one control unit. The photovoltaic cells are disposed on the substrate and each generates a photocurrent respectively. Each photovoltaic cell includes a first conductive layer, a photovoltaic layer and a second conductive layer. The first conductive layer is disposed on the substrate. The photovoltaic layer is disposed on the first conductive layer and having an opening exposing the first conductive layer. The second conductive layer is disposed on the photovoltaic layer through the opening and electrically connected to the first conductive layer of the adjacent photovoltaic cell. The control unit is electrically connected to the photovoltaic cells. Wherein, when the control unit examines that at least one photocurrent generated by the photovoltaic cells is different from the photocurrents generated by the other photovoltaic cells, the control unit provides a compensable current to the photovoltaic cells in order to obtain current matching of photocurrents generated by the overall photovoltaic cells.

The present invention further provides a thin film solar cell including a substrate, a plurality of first photovoltaic cells and at least one second photovoltaic cell. The first photovoltaic cells are disposed on the substrate and each of them is adapted to generate a photocurrent respectively. Wherein, each of the first photovoltaic cells includes a first conductive layer, a photovoltaic layer and a second conductive layer. The first conductive layer is disposed on the substrate. The photovoltaic layer is disposed on the first conductive layer and having an opening exposing the first conductive layer. The second conductive layer is disposed on the photovoltaic layer through the opening and electrically connected to the first conductive layer of the adjacent first photovoltaic cell. The second photovoltaic cell is disposed on the substrate. When the photocurrents generated by the first photovoltaic cells are different, the second photovoltaic cell is electrically connected to at least a part of the first photovoltaic cells in order to obtain current matching of the photocurrents generated by the overall first photovoltaic cells.

The present invention also provides a thin film solar cell system including a plurality of thin film solar cell modules and at least one current matching module. The thin film solar cell modules are connected in electrical series with one another and each providing a photocurrent respectively. Each of the thin film solar cell modules at least includes a substrate, a first conductive layer, a photovoltaic layer and a second conductive layer. The first conductive layer is disposed on the substrate. The photovoltaic layer is disposed on the first conductive layer. The second conductive layer is disposed on the photovoltaic layer. When the photocurrent provided by at least one of the thin film solar cell modules is different from the photocurrents provided by the other thin film solar cell modules, the current matching module is electrically connected to the thin film solar cell module in order to obtain current matching of the photocurrents provided by the thin film solar cell modules.

The present invention further provides a thin film solar cell system including a plurality of thin film solar cell modules. The thin film solar cell modules are connected in electrical series with one another and each providing a photocurrent respectively. Each of the thin film solar cell modules at least includes a substrate, a plurality of first photovoltaic cells and at least a second photovoltaic cell. The first photovoltaic cells are disposed on the substrate, and each of the first photovoltaic cells includes a first conductive layer, a photovoltaic layer and a second conductive layer. The first conductive layer is disposed on the substrate. The photovoltaic layer is disposed on the first conductive layer. The second conductive layer is disposed on the photovoltaic layer. At least a second photovoltaic cell is disposed on the substrate. When the photocurrent provided by at least one of the thin film solar cell modules is different from the photocurrents provided by the other thin film solar cell modules, the second photovoltaic cell of the thin film solar cell module is electrically connected in parallel to at least a part of the first photovoltaic cells of the thin film solar cell modules in order to obtain current matching of the photocurrents provided by the thin film solar cell modules.

In view of the above, the thin film solar cell of the present invention is designed with the control unit. Thus, when the photocurrents provided by the first photovoltaic cells are different, the current matching can be obtained by electrically connecting the second photovoltaic cell to the part of the first photovoltaic cell. And the overall photoelectric conversion efficiency can be improved.

Moreover, the thin film solar cell of the present invention is designed with a second photovoltaic cell. When the photocurrents provided by the first photovoltaic cells are different, the second photovoltaic cell can be electrically connected to a part of the first photovoltaic cells in order to obtain current matching of the photocurrents to improve the overall photoelectric conversion efficiency.

Moreover, the thin film solar cell system of the present invention includes at least a current matching module. When the photocurrents provided by the plurality of thin film solar cells are different, the current matching can be electrically connected to the thin film solar cell modules in order to obtain current matching of the photocurrents provided by the thin film solar cell modules. In addition, each of the thin film solar cell modules in an embodiment of the present invention includes a second photovoltaic cell. When the photocurrents provided by the thin film solar cell modules are different, the second photovoltaic cell of the thin film solar cell module can be electrically connected in parallel to a part of the first photovoltaic cells of the thin film solar cell modules in order to obtain the current matching of the photocurrents provided by the thin film solar cell modules.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 schematically illustrates a thin film solar cell according to an embodiment of the present invention.

FIG. 2 schematically illustrates a cross-sectional view along the B-B′ line of FIG. 1 of the thin film solar cell.

FIG. 3 schematically illustrates a process flow of manufacturing and optimization of a thin film solar cell according to an embodiment of the present invention.

FIG. 4 schematically illustrates a process flow of the photovoltaic cell of FIG. 3 formed on the substrate.

FIG. 5 schematically illustrates a top view of a thin film solar cell according to an embodiment of the present invention.

FIG. 6 schematically illustrates a cross-sectional view of a thin film solar cell of FIG. 5 along the B-B′ line.

FIG. 7 schematically illustrates a cross-sectional view of a thin film solar cell of FIG. 5 along the C-C′ line, wherein the first photovoltaic cell and the second photovoltaic cell is not electrically connected.

FIG. 8 schematically illustrates a cross-sectional view of FIG. 5 along the C-C′ line, an embodiment of wherein the first photovoltaic cell and the second photovoltaic cell are electrically connected.

FIG. 9 schematically illustrates a top view of a thin film solar cell according to an embodiment of the present invention.

FIG. 10 schematically illustrates a top view of a thin film solar cell according to an embodiment of the present invention.

FIG. 11 schematically illustrates a top view of a thin film solar cell according to an embodiment of the present invention.

FIGS. 12A to 12G schematically illustrate a process flow of manufacturing a thin film solar cell according to an embodiment of the present invention.

FIGS. 13A and 13B schematically illustrate a method of electrically connecting between the first photovoltaic cell and the second photovoltaic cell according to an embodiment of the present invention.

FIG. 14 schematically illustrates a thin film solar cell system according to an embodiment of the present invention.

FIG. 15 schematically illustrates a cross-sectional view of a thin film solar cell of FIG. 14 along the A-A′ line.

FIG. 16 schematically illustrates an embodiment of the electrically connecting of the first photovoltaic cell and the second photovoltaic cell.

FIG. 17 schematically illustrates a top view of a thin film solar cell system according to an embodiment of the present invention, wherein the current matching module and the thin film solar cell module are electrically connected in another way.

FIG. 18 schematically illustrates a top view of a thin film solar cell system according to an embodiment of the present invention.

FIG. 19 schematically illustrates a cross-sectional view of a thin film solar cell module of FIG. 18 along the B-B′ line.

FIG. 20 schematically illustrates a cross-sectional view of FIG. 18 along the C-C′ line, an embodiment of wherein the first photovoltaic cell and the second photovoltaic cell are electrically connected.

### DETAILED DESCRIPTION OF THE INVENTION

Reference will now be made in detail to the present preferred embodiments of the invention, examples of which are illustrated in the accompanying drawings. Wherever possible, the same reference numbers are used in the drawings and the description to refer to the same or like parts.

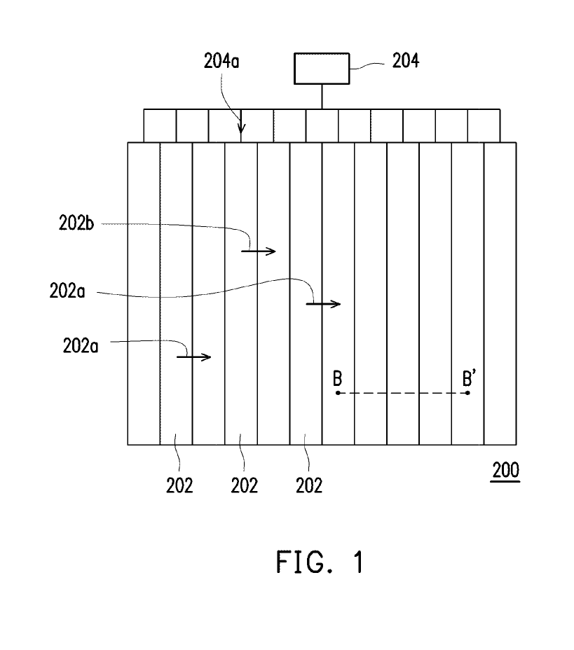

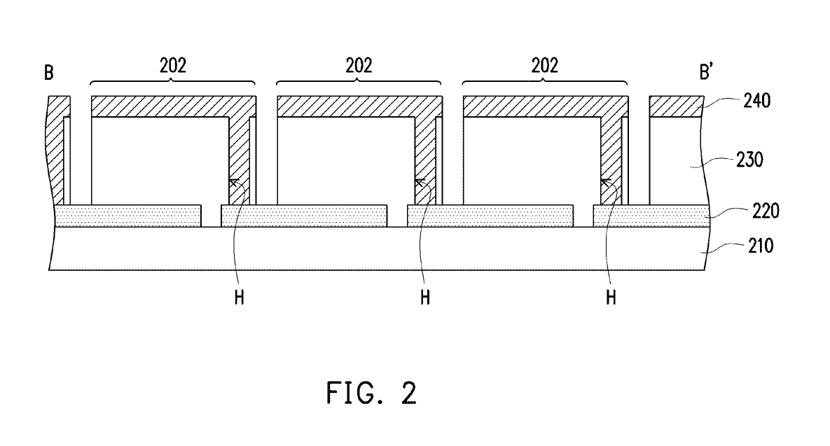

FIG. 1 schematically illustrates a thin film solar cell according to an embodiment of the present invention. FIG. 2 schematically illustrates a cross-sectional view along the B-B′ line of FIG. 1 of the thin film solar cell. Referring to FIG. 1 and FIG. 2, a thin film solar cell 200 includes a substrate 210, a plurality of photovoltaic cells 202 and at least a control unit 204. In this embodiment, the substrate 210 can be a transparent substrate, such as a glass substrate.

The photovoltaic cells 202 are disposed on the substrate 210, and each of them generates photocurrents 202a and 202b after illuminated respectively. In which each of the photovoltaic cells 202 includes a first conductive layer 220, a photovoltaic layer 230 and a second conductive layer 240. In details, the first conductive layer 220 is disposed on the substrate 210. The photovoltaic layer 230 is disposed on the first conductive layer 220 and having an opening H exposing the first conductive layer 220. The second conductive layer 240 is disposed on the photovoltaic layer 230 through the opening H and electrically connected to the first conductive layer 220 of the adjacent photovoltaic cell 202, as shown in FIG. 2. Precisely speaking, the above mentioned photovoltaic cells 202 are connected in electrical series to one another, for example.

In this embodiment, the first conductive layer 220 is a transparent conductive layer, for example, and the material thereof can be at least one of the zinc oxide, indium tin oxide (ITO), indium zinc oxide (IZO), indium tin zinc oxide (ITZO), aluminium tin oxide (ATO), aluminium zinc oxide (AZO), cadmium indium oxide (CIO), cadmium zinc oxide (CZO), gallium zinc oxide (GZO) and fluorine tin oxide (FTO). In another embodiment (not shown), the first conductive layer 220 can be a stacked layer of a reflective layer (not shown) and the above-mentioned transparent conductive layer, and the reflective layer is disposed between the transparent conductive layer and the substrate. The material of the reflective layer can be a metal with higher reflectivity, such as aluminium (Al), silver (Ag), molybdenum (Mo) or copper (Cu).

In this embodiment, the material of the photovoltaic layer 230 can be a semiconductor thin film in Group IV elements of the Periodic Table, Group III-V compound semiconductor thin film, Group II-VI compound semiconductor thin film, organic semiconductor thin film or compound thereof. In details, the semiconductor thin film in Group IV elements of the Periodic Table is at least one of a carbon thin film, a silicon thin film, a germanium thin film, a silicon carbide thin film and a silicon germanium thin film, each of which may be in monocrystalline form, polycrystalline form, amorphous form or microcrystalline form, or a combination thereof. For example, the compound semiconductor thin film in Group III-V of the Periodic Table is at least one of gallium arsenide (GaAs) thin film and indium gallium phosphide (InGaP) thin film, or a combination thereof. The compound semiconductor thin film in Group II-VI, for example, includes at least one of a copper indium diselenide (CIS) thin film, a copper indium gallium diselenide (GIGS) thin film and a cadmium telluride (CdTe) thin film, or a combination thereof. Furthermore, the above mentioned organic compound semiconductor thin film can be a mixture of a conjugated polymer donor and PCBM acceptor.

In addition, the film structure of the above mentioned photovoltaic layer 230 can be a PN single layer of photoelectric conversion structure composed of P-type semiconductor and N-type semiconductor or a PIN single layer of photoelectric conversion structure composed of P-type semiconductor, intrinsic layer and N-type semiconductor. However, the present invention is not limited thereto. In another embodiment, the film structure of the photovoltaic layer 230 can be a stacked structure of a tandem junction, a triple junction or more than three-layers of photoelectric conversion film structure.

In this embodiment, the material of the above-mentioned transparent conductive layer can be used in the second conductive layer 240, and the details are not iterated herein. In this embodiment, the second conductive layer 240 can further include a reflective layer disposed on the transparent conductive layer. It is noted that when the second conductive layer 240 includes a reflective layer, the first conductive layer 220 can only be a transparent conductive layer. On the contrary, when the first conductive layer 220 includes a reflective layer, the second conductive layer 240 can only be a transparent conductive layer without a reflective layer thereon. In an embodiment, each of the first conductive layer 220 and the second conductive layer 250 can be a single transparent conductive layer without a reflective layer thereon. In other words, the design of the first conductive layer 220 and the second conductive layer 240 can be adjusted according to the users' requirements (e.g. for manufacturing a thin film solar cell with double-sided illumination or a thin film solar cell with one-sided illumination). The design of the first conductive layer 220 and the second conductive layer 240 described above is provided only for illustration purposes, and is not construed as limiting the present invention.

Referring to FIG. 1, the control unit 204 is electrically connected to the photovoltaic cell 202, wherein the photocurrent generated by the photovoltaic cell 202 after illuminated 202a can be readily detected by the control unit 204. Photocurrents 202a generated by some of the photovoltaic cells 202 may be different in magnitude. It may due to the process variation or other factors in the manufacturing process and result the photocurrent unmatching condition. In other words, when at least one of the photocurrents 202b generated by the photovoltaic cell 202 is different in magnitude from the photocurrents 202a generated by the other photovoltaic cell 202, the control unit 204 can automatically provide a compensable current 204a to the photovoltaic cells 202 which generates the photocurrents 202b in order to obtain the current matching of the photocurrents generated by the overall photovoltaic cells 202. Wherein in order to make the current to be superimposed, the control unit 204 is electrically connected in parallel to each of the photovoltaic cells 202.

In other words, since the photovoltaic cells 202 are electrically connected in series with one another in the thin film solar cell 200, the overall photoelectric conversion efficiency will be restricted due to the current unmatching condition resulted by when the magnitude of the photocurrent 202b generated by some of the photovoltaic cells 202 is less than the photocurrent 202a generated by other photovoltaic cells 202. Thus, the control unit 204 of this embodiment not only can readily detect the photocurrents 202a and 202b generated by the photovoltaic cells 202, but also can provide a compensable current 204a to the photovoltaic cells 202 which generate the smaller photocurrent 202b. Wherein the control unit 204 and the photovoltaic cell 202 are electrically connected in parallel, so the output of the photocurrent 202b generated by the photovoltaic cell 202 can be improved to make all the photocurrents 202a and 202b generated by the photovoltaic cells 202 which are connected in series to be current matching. In this way, the photoelectric conversion efficiency of the thin film solar cell 200 can be improved.

In this embodiment, the control unit 204 is an Application-Specific Integrated Circuit (ASIC), for example. Wherein, the control unit 204 can be connected to each of the photovoltaic cells 202 by means of external electrical connection, such as a conducting wire or a bonding wire method. Additionally, since the control unit 204 is electrically connected to each of the photovoltaic cells 202 in parallel, the anode and cathode of the control unit 204 is electrically connected to the first conductive layer 220 and the second conductive layer 240, respectively. FIG. 1 illustrates the number of control units 204 is one as an example. But in another embodiment, the control units 204 can be in a plurality. This means that every single photovoltaic cell 202 can be electrically connected in parallel to a control unit 204 in order to control the photocurrent generated by each of the photovoltaic cells 202. The number of control units 204 can be decided according to the users' requirement and design, the present invention is not limited thereto. In addition, when the number of control units 204 is more than two, the control units 204 can be placed at the same side or different side of the photovoltaic cells 202. It means that the control unit 204 can be placed around the photovoltaic cells 202. In another embodiment, the control unit 204 can also be obtained by the way the semiconductor manufacturing process of integrating the above mentioned ASIC to the layer of photovoltaic cell 202.

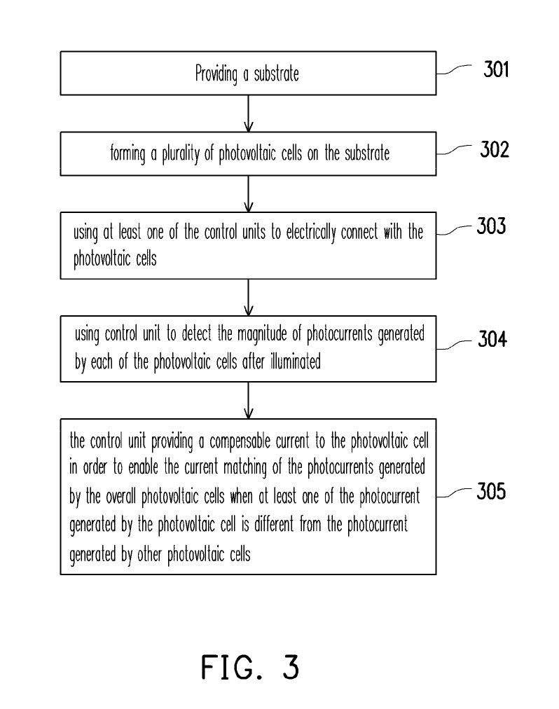

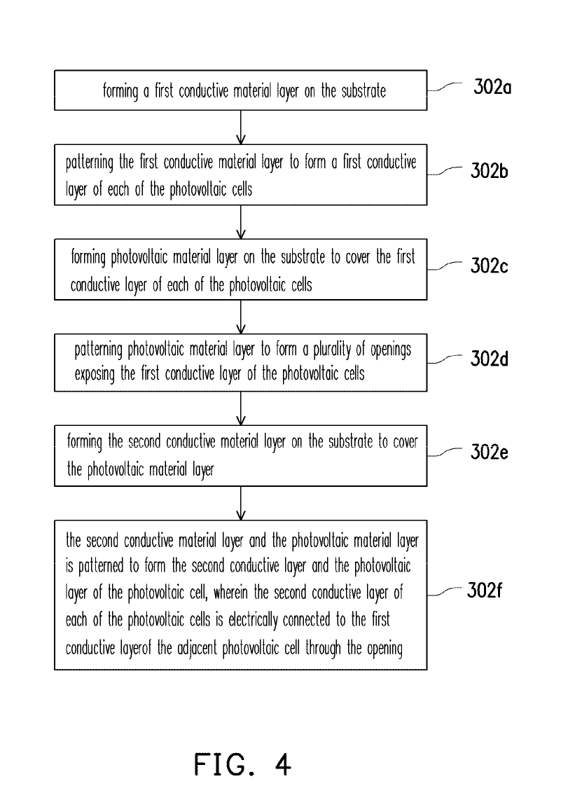

The following describes the method of manufacturing and optimization of the above mentioned thin film solar cell 200. FIG. 3 schematically illustrates a process flow of manufacturing and optimization of a thin film solar cell according to an embodiment of the present invention. FIG. 4 schematically illustrates a process flow of the photovoltaic cell of FIG. 3 formed on the substrate. Referring to FIG. 3 and FIG. 4, first of all, the above mentioned substrate 210 is provided, and the substrate 210 is a glass substrate, for example.

And then step 302 is proceeded to and formed a plurality of above mentioned photovoltaic cells 202 on the substrate 210 as shown in FIG. 2. In this embodiment, the method to form the photovoltaic cell 202 is as illustrated in the step flow chart of FIG. 4. In details, referring to step 302a of FIG. 4, the first conductive material layer is formed on the substrate 210 (not shown), wherein the above mentioned transparent conductive material, for example, is used in the first conductive material layer and the method to form the first conductive material layer is sputtering, chemical vapour deposition (CVD) or evaporation.

Then, step 302b of FIG. 4 is proceeded to. The first conductive material layer is patterned to form the above mentioned first conductive layer 220 of each of the photovoltaic cells 202 as shown in FIG. 2. In this embodiment, laser etching method is taken as an example for the method to pattern the first conductive material layer and any other appropriate etching process can be used in another embodiment. Afterward, step 302c of FIG. 4 is proceeded to. Photovoltaic material layer is formed on the substrate 210 (not shown) to cover the first conductive layer 220 of the photovoltaic cells 202. In this embodiment, the method to form the photovoltaic layer 230, for example, can be Radio Frequency Plasma Enhanced Chemical Vapour Deposition (RF PECVD), Very High Frequency Plasma Enhanced Chemical Vapour Deposition (VHF PECVD) or Microwave Plasma Enhanced Chemical Vapour Deposition (MW PECVD).

After that, step 302d of FIG. 4 is proceeded to. Photovoltaic material layer is patterned to form a plurality of openings H, wherein the openings H are exposing the first conductive layer 220 of the photovoltaic cells 202, respectively, as shown in FIG. 2. In this embodiment, the method to form the number of openings H is, for example, using the laser cutting, etching or mechanical removal process. And proceed to step 302e of FIG. 4, the second conductive material layer is formed on the substrate 210 to cover the photovoltaic material layer. In which the second conductive layer 240 is generally used as the back contact of the photovoltaic cells 202 as shown in FIG. 2. In this embodiment, the method to form the second conductive layer 240 is, for example, sputtering, chemical vapour deposition (CVD) or evaporation and the material can be the above mentioned transparent conductive material. The details are not iterated herein.

Hereafter, step 302f of FIG. 4 is proceeded to. The second conductive material layer and the photovoltaic material layer is patterned to form the second conductive layer 240 and the photovoltaic layer 230 of the photovoltaic cell 202 as shown in FIG. 2. Wherein, the second conductive layer 240 of each of the photovoltaic cells 202 is electrically connected to the first conductive layer 220 of the adjacent photovoltaic cell 202 through the opening H. At this point, the formation of photovoltaic cell 202 on the substrate 210 which is shown in step 302 of FIG. 3 can be completed by following the steps 302a to 302f of FIG. 4 in sequence.

After completing above mentioned step 302, step 303 of FIG. 3 is proceeded to. At least one of the control units 204 is electrically connected to the photovoltaic cells 202 as shown in FIG. 1. In this embodiment, the method of electrically connecting the control unit 204 to the photovoltaic cell 202 can be the laser welding process or wire bonding process. In another embodiment, the method of electrically connecting the control unit 204 to the photovoltaic cell 202 can be integrating the control unit 204 into the layer of photovoltaic cell 202. Wherein, the anode and the cathode of the control unit 204 is electrically connected to the first conductive layer 220 and the second conductive layer 240 of each of the photovoltaic cells 202, respectively.

Then, referring to FIG. 1 and step 304 of FIG. 3, the above mentioned control unit 204 is used to detect the magnitude of photocurrents 202a and 202b generated by each of the photovoltaic cells 202 after illuminated. Finally, in step 305, when at least one of the photocurrent 202a generated by the photovoltaic cell 202 is different from the photocurrent 202b generated by other photovoltaic cells 202, the control unit 204 will provide the above mentioned compensable current 204a to the photovoltaic cell 202 in order to enable the current matching of the photocurrents generated by the overall photovoltaic cells 202. Wherein, the details of current matching mechanism are illustrated in above mentioned embodiment for reference and the details are not iterated herein. After completing the steps 301 to 305, method of manufacturing and optimization of a thin film solar cell is completed.

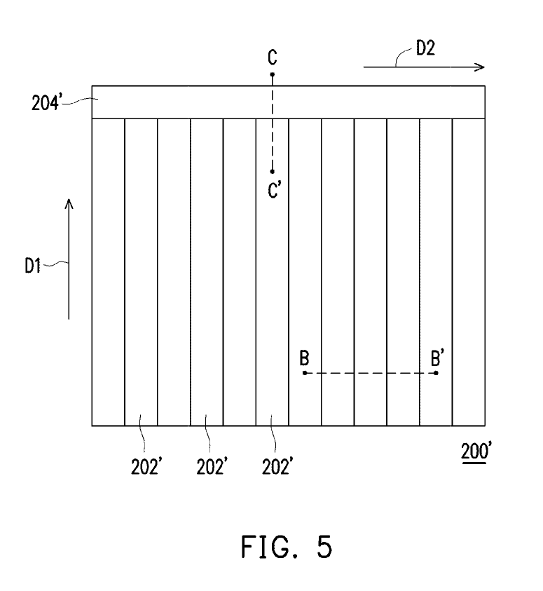

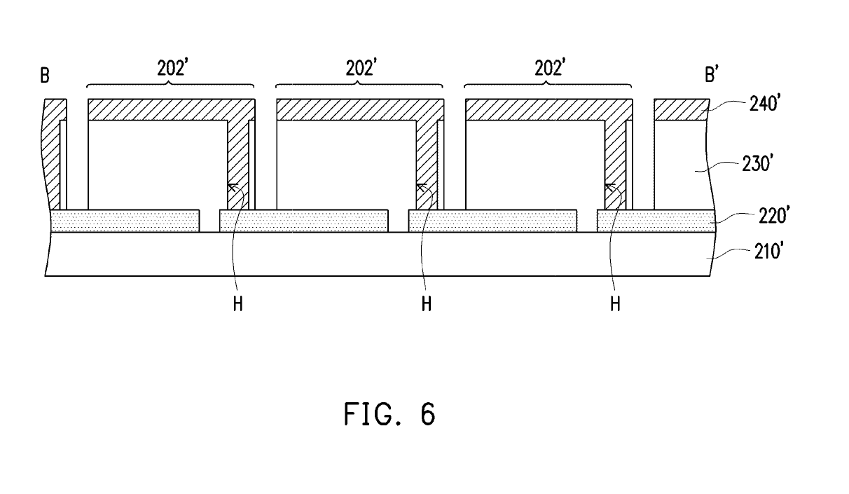

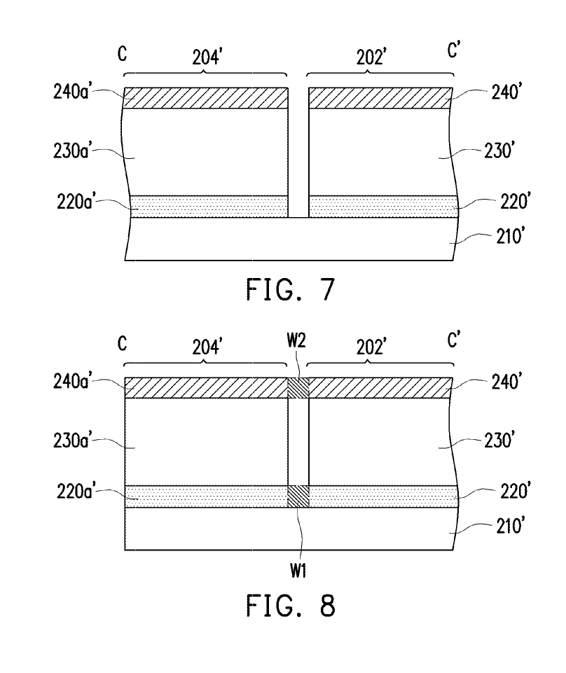

FIG. 5 schematically illustrates a top view of a thin film solar cell according to an embodiment of the present invention. FIG. 6 schematically illustrates a cross-sectional view of a thin film solar cell of FIG. 5 along the B-B′ line. FIG. 7 schematically illustrates a cross-sectional view of a thin film solar cell of FIG. 5 along the C-C′ line, wherein the first photovoltaic cell and the second photovoltaic cell is not electrically connected. And FIG. 8 schematically illustrates a cross-sectional view of FIG. 5 along the C-C′ line, an embodiment of wherein the first photovoltaic cell and the second photovoltaic cell are electrically connected. Referring to FIG. 5 to FIG. 7, a thin film solar cell 200′ includes a substrate 210′, a plurality of photovoltaic cells 202′ and a second photovoltaic cell 204′. In this embodiment, the substrate 210′ can be a transparent substrate, such as a glass substrate. The second photovoltaic cell 204′ expands in an expansion direction D2′. And the first photovoltaic cell 202′ expands in an expansion direction D1′, for example, wherein the expansion direction D2′ is perpendicular to the expansion direction D1′. This means that the first photovoltaic cell 202′ can be arranged in the expansion direction D2′. The above description depends on the user's requirement, it is provided only for illustration purposes, and is not construed as limiting the present invention.

The first photovoltaic cells 202′ are disposed on the substrate 210′, and each of them generates photocurrents after illuminated respectively. In which each of the first photovoltaic cells 202′ includes a first conductive layer 220′, a photovoltaic layer 230′ and a second conductive layer 240′. In details, the first conductive layer 220′ is disposed on the substrate 210′. The photovoltaic layer 230′ is disposed on the first conductive layer 220′ and having an opening H′ exposing the first conductive layer 220′. The second conductive layer 240′ is disposed on the photovoltaic layer 230′ through the opening H′ and electrically connected to the first conductive layer 220′ of the adjacent photovoltaic cell 202′, as shown in FIG. 6. Precisely speaking, the above mentioned first photovoltaic cells 202′ are connected in electrical series to one another, for example.

In this embodiment, the first conductive layer 220′ is a transparent conductive layer, for example, and the material thereof can be at least one of the zinc oxide, indium tin oxide (ITO), indium zinc oxide (IZO), indium tin zinc oxide (ITZO), aluminium tin oxide (ATO), aluminium zinc oxide (AZO), cadmium indium oxide (CIO), cadmium zinc oxide (CZO), gallium zinc oxide (GZO) and fluorine tin oxide (FTO). In another embodiment (not shown), the first conductive layer 220′ can be a stacked layer of a reflective layer (not shown) and the above-mentioned transparent conductive layer, and the reflective layer is disposed between the transparent conductive layer and the substrate. The material of the reflective layer can be a metal with higher reflectivity, such as aluminium (Al), silver (Ag), molybdenum (Mo) or copper (Cu).

In this embodiment, the material of the photovoltaic layer 230′ can be a semiconductor thin film in Group IV elements of the Periodic Table, Group III-V compound semiconductor thin film, Group II-VI compound semiconductor thin film, organic semiconductor thin film or compound thereof. In details, the semiconductor thin film in Group IV elements of the Periodic Table is at least one of a carbon thin film, a silicon thin film, a germanium thin film, a silicon carbide thin film and a silicon germanium thin film, each of which may be in monocrystalline form, polycrystalline form, amorphous form or microcrystalline form, or a combination thereof. For example, the compound semiconductor thin film in Group III-V of the Periodic Table is at least one of gallium arsenide (GaAs) thin film and indium gallium phosphide (InGaP) thin film, or a combination thereof. The compound semiconductor thin film in Group II-VI, for example, includes at least one of a copper indium diselenide (CIS) thin film, a copper indium gallium diselenide (CIGS) thin film and a cadmium telluride (CdTe) thin film, or a combination thereof. Furthermore, the above mentioned organic compound semiconductor thin film can be a mixture of a conjugated polymer donor and PCBM acceptor.

In addition, the film structure of the above mentioned photovoltaic layer 230′ can be a PN single layer of photoelectric conversion structure composed of P-type semiconductor and N-type semiconductor or a PIN single layer of photoelectric conversion structure composed of P-type semiconductor, intrinsic layer and N-type semiconductor. However, the present invention is not limited thereto. In another embodiment, the film structure of the photovoltaic layer 230 can be a stacked structure of a tandem junction, a triple junction or more than three-layers of photoelectric conversion film structure.

In this embodiment, the material of the above-mentioned transparent conductive layer can be used in the second conductive layer 240′, and the details are not iterated herein. In this embodiment, the second conductive layer 240′ can further include a reflective layer disposed on the transparent conductive layer. It is noted that when the second conductive layer 240′ includes a reflective layer, the first conductive layer 220′ can only be a transparent conductive layer. On the contrary, when the first conductive layer 220′ includes a reflective layer, the second conductive layer 240′ can only be a transparent conductive layer without a reflective layer thereon. In an embodiment, each of the first conductive layer 220′ and the second conductive layer 250′ can be a single transparent conductive layer without a reflective layer thereon. In other words, the design of the first conductive layer 220′ and the second conductive layer 240′ can be adjusted according to the users' requirements (e.g. for manufacturing a thin film solar cell with double-sided illumination or a thin film solar cell with one-sided illumination). The design of the first conductive layer 220′ and the second conductive layer 240′ described above is provided only for illustration purposes, and is not construed as limiting the present invention.

Referring to FIG. 5 and FIG. 7, the second photovoltaic cell 204′ is disposed on the substrate 210′. Wherein, when the photocurrents generated by the first photovoltaic cells 202′ is different, the second photovoltaic cell 204′ can be electrically connected to at least part of the first photovoltaic cells 202′ in order to obtain current matching of the photocurrents generated by the first photovoltaic cells 202′. For example, since the first photovoltaic cells 202′ are electrically connected in series with one another in the thin film solar cell 200′, the overall photoelectric conversion efficiency will be restricted due to the current unmatching condition resulted by when the magnitude of the photocurrent generated by some of the first photovoltaic cells 202′ is less than the photocurrent generated by other first photovoltaic cells 202′. Thus, the second photovoltaic cell 204′ of this embodiment and the first photovoltaic cell 202′ can be electrically connected in parallel, so the output of the photocurrent generated by the first photovoltaic cell 202′ can be improved to make all the photocurrents generated by the first photovoltaic cells 202′ which are connected in series to be current matching. In this way, the photoelectric conversion efficiency of the thin film solar cell 200′ can be improved.

In this embodiment, the second photovoltaic cell 204′ includes a first conductive layer 220a′, a photovoltaic layer 230a′ and a second conductive layer 240a′. Similar to the above mentioned first photovoltaic cell 202′, the first conductive layer 220a′ of the second photovoltaic cell 204′ is disposed on the substrate 210′. The photovoltaic layer 230a′ is disposed on the first conductive layer 220a′ and the second conductive layer 240a′ is disposed on the photovoltaic layer 230a′. In an embodiment, if the magnitude of photocurrent generated by one of the above mentioned first photovoltaic cells 202′ is smaller than photocurrent generated by other first photovoltaic cells 202′, the second photovoltaic cell 204′ is adapted to electrically connect to the first photovoltaic cell 202′ in order to make the photocurrent generated by the first photovoltaic cell 202′ and the photocurrent generated by other first photovoltaic cell 202′ be current matching. In details, the electrical connection of the first photovoltaic cell 202′ and the second photovoltaic cell 204′ is illustrated in FIG. 8. Wherein, for example, the first conductive layer 220a′ of the second photovoltaic cell 204′ is electrically connected to the first conductive layer 220′ of the first photovoltaic cell 202′ through the welding zone W1′, and the second conductive layer 240a′ of the second photovoltaic cell 204′ is electrically connected to the second conductive layer 240′ of the first photovoltaic cell 202′ through the welding zone W2′. That is the second photovoltaic cell 204′, for example, is electrically connected in parallel to the first photovoltaic cell 202′ which generates the smaller photocurrent, wherein each of the welding zone W1′ and W2′ represents a welding point. The present invention is not limited thereto.

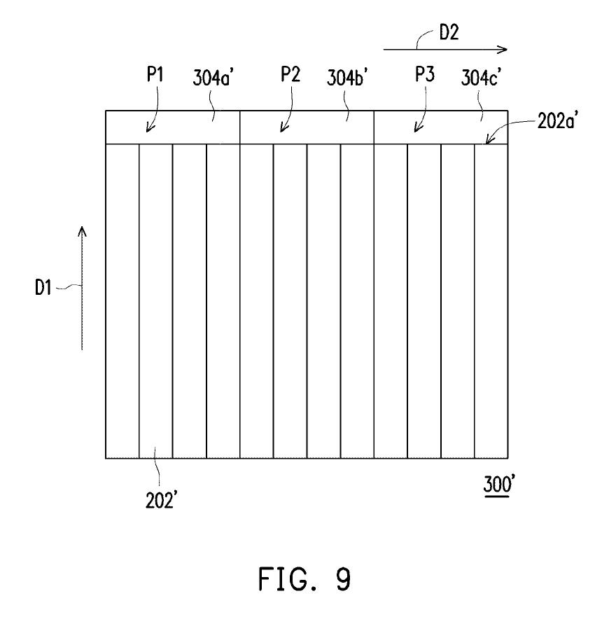

FIG. 9 schematically illustrates a top view of a thin film solar cell according to an embodiment of the present invention. Referring to FIG. 9, the component of thin film solar cell 300′ is similar to above mentioned thin film solar cell 200′. In which the same component is illustrated in the same symbol and the details are not iterated herein.

In this embodiment, the thin film solar cell 300′ includes three second photovoltaic cells 304a′, 304b′ and 304c′ and every four of first photovoltaic cells 202′ corresponds to each of the second photovoltaic cells 304a′, 304b′ and 304c′. For example, when the photocurrent generated by each of the first photovoltaic cell 202′ which is one of the four first photovoltaic cells 202′ corresponding to the second photovoltaic cell 304a′ is different in magnitude, the second photovoltaic cell 304a′ can be electrically connected to the first photovoltaic cell 202′, the one which generates the smallest photocurrent, in order to make the photocurrents of that four first photovoltaic cells 202′ current matching. Similarly, the same way can be used to obtain current matching by electrically connecting the second photovoltaic cell 304b′ and the second photovoltaic cell 304c′ to an adjacent first photovoltaic cell 202′, respectively. In this way, the overall photoelectric conversion efficiency of the thin film solar cell 300′ can be improved.

However, neither the number of second photovoltaic cells 304a′, 304b′ and 304c′ nor that of first photovoltaic cells 202′ which correspond to second photovoltaic cells 304a′, 304b′ and 304c′ is not limited in present invention. In other embodiment, the number of second photovoltaic cells 304′ can be two, three or more. And the number of first photovoltaic cells 202′ which correspond to second photovoltaic cells 304a′, 304b′ and 304c′ can also be changed according to users' requirement.

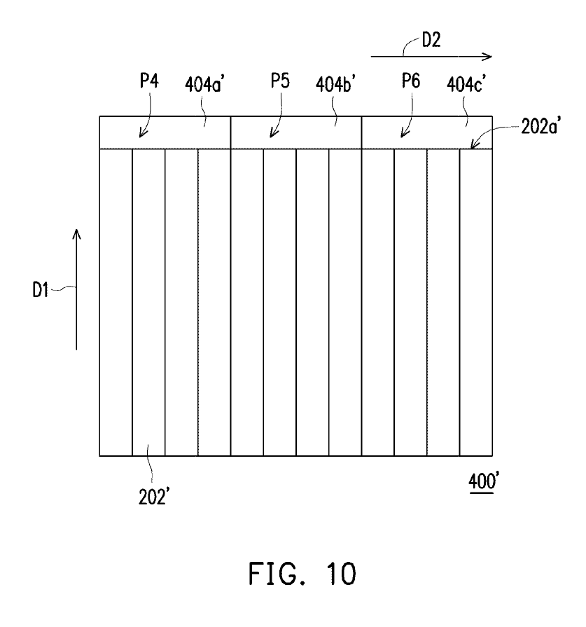

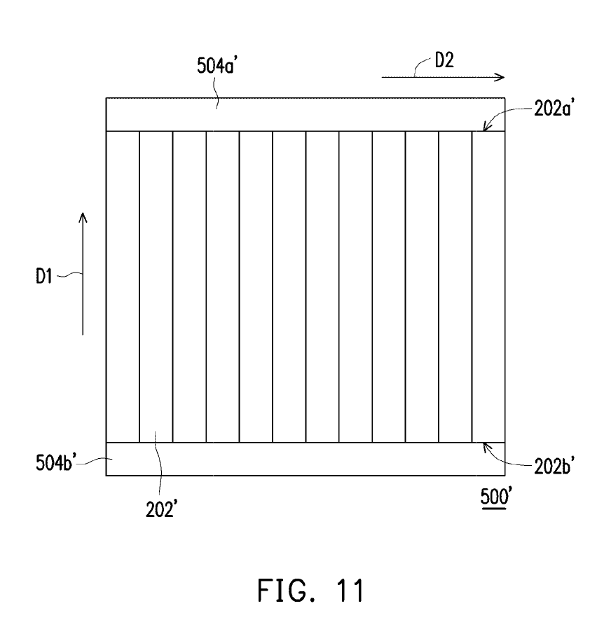

On the other hand, in the thin film solar cell 300′, each of the second photovoltaic cells 304a′, 304b′ and 304c′ includes a photovoltaic zone P1′, P2′ and P3′, respectively. And areas of each of the photovoltaic zone P1′, P2′ and P3′ of the second photovoltaic cells 304a′, 304b′ and 304c′ are the same. But the present invention is not limited thereto. FIG. 10 schematically illustrates a top view of a thin film solar cell according to an embodiment of the present invention. FIG. 11 schematically illustrates a top view of a thin film solar cell according to an embodiment of the present invention. In another embodiment as shown in FIG. 10, the areas of photovoltaic zone P4′ of second photovoltaic cells 404a′, photovoltaic zone P5′ of second photovoltaic cells 404b′ and photovoltaic zone P6′ of second photovoltaic cells 404c′ are not the same with each other.

In the embodiment illustrated in FIG. 9, all of the second photovoltaic cells 304a′, 304b′ and 304c′ are placed at one side 202a′ of first photovoltaic cell 202, i.e., at one end of the first photovoltaic cell 202′ of the expansion direction D1'. And in the embodiment illustrated in FIG. 10, all of the second photovoltaic cells 404a′, 404b′ and 404c′ are placed at one side 202a′ of first photovoltaic cell 202′. Yet the thin film solar cell 500′ of another embodiment as illustrated in FIG. 11, wherein, the second photovoltaic cell 504a′ is placed at one side 202a′ of first photovoltaic cell 202′ and the second photovoltaic cell 504b′ is placed at the other side 202b′ of first photovoltaic cell 202′. This means that the second photovoltaic cell 504a′ and the second photovoltaic cell 504b′ are placed at the opposite ends of first photovoltaic cell 202′ of the expansion direction D1'. Thus the locations of the second photovoltaic cells are not limited in present invention. In some embodiments the second photovoltaic cells can placed at different sides of first photovoltaic cells.

In other embodiment (not shown), when the photocurrents generated by first photovoltaic cells are in good current matching conditions, the second photovoltaic cells can be electrically connected in series to first photovoltaic cells. Otherwise, the second photovoltaic cells can be divided into a plurality of subunits. Each of the subunits can be electrically connected in parallel to the first photovoltaic cells respectively in order to make full use of the second photovoltaic cells to generate photocurrents. In this way, the areas of the second photovoltaic cells being occupied in the thin film solar cell will not be wasted.

The following describes the manufacturing method of the above mentioned thin film solar cell 200′ with the illustrations of the cross-sectional structure along the B-B′ line and C-C′ line of FIG. 5 and the steps, accordingly.

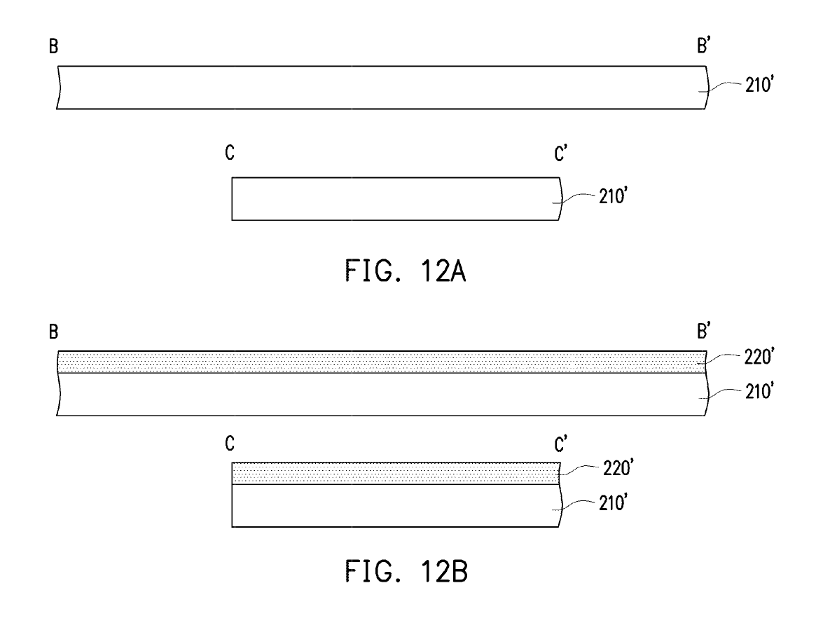

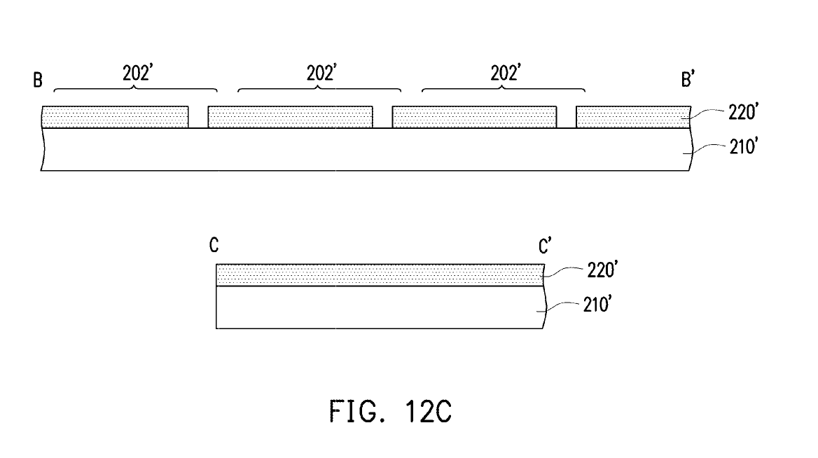

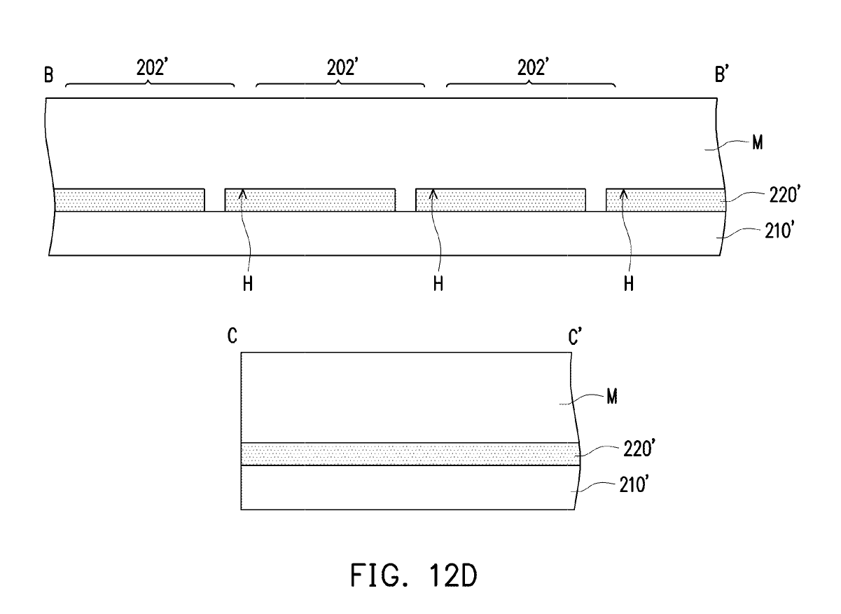

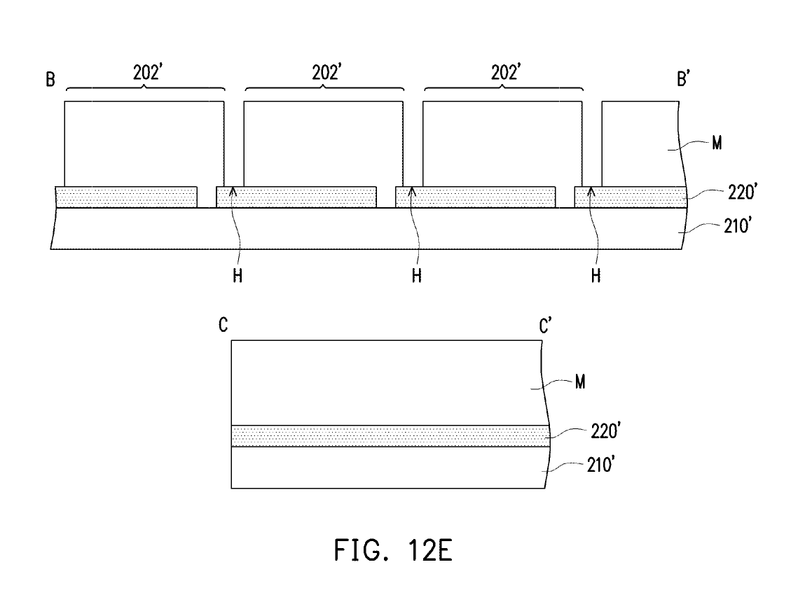

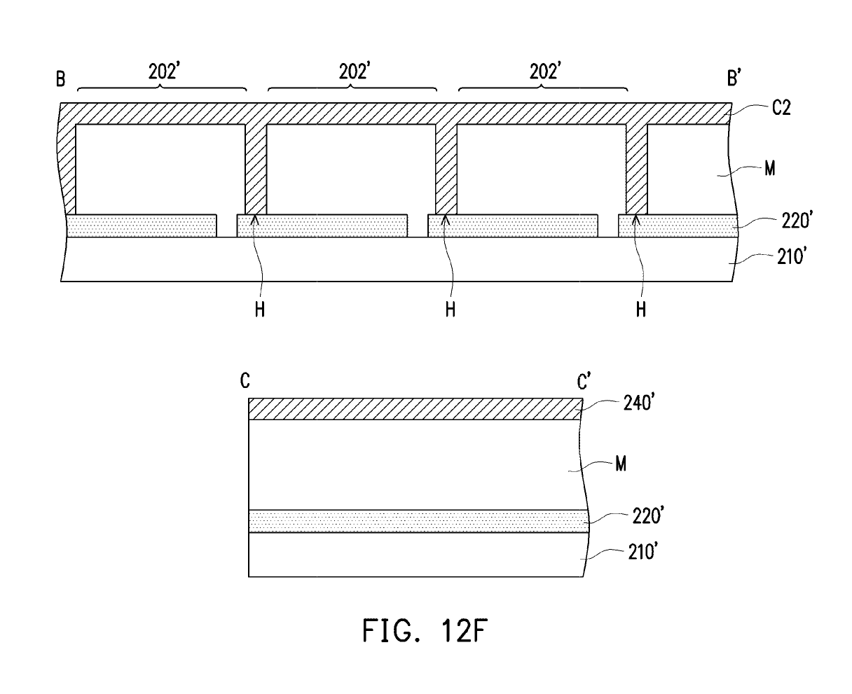

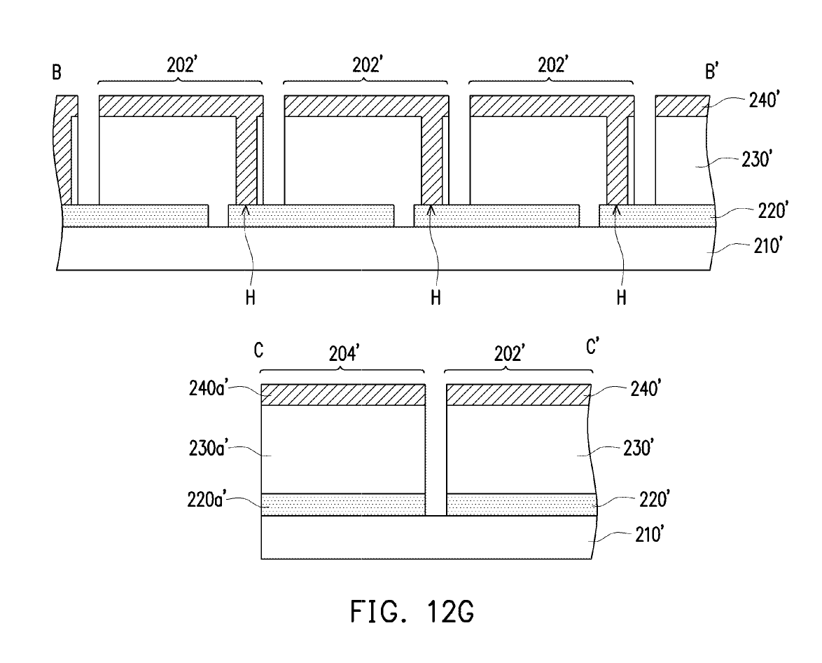

FIGS. 12A to 12G schematically illustrate a process flow of manufacturing a thin film solar cell according to an embodiment of the present invention. Referring to FIG. 12A, at first the substrate 210′ is provided. And the substrate 210′ can be a glass substrate, for example.

After that, as shown in FIG. 10B, the first conductive material layer C1′ is formed on the substrate. In this embodiment, the first conductive material layer C1′ can be the above mentioned transparent conductive material, for example. And the method to form the first conductive material layer is sputtering, chemical vapour deposition (CVD) or evaporation.

Then, as shown in FIG. 10C, first conductive material layer C1′ is patterned to form first conductive layer 220′ of each of the first photovoltaic cells 202′. In this embodiment, laser etching method is taken as an example for the method to pattern the first conductive material layer C1′ and any other appropriate etching process can be used in another embodiment.

Afterward, as shown in FIG. 10D, photovoltaic material layer M′ is formed on the substrate to cover the first conductive layer 220′ of the first photovoltaic cells 202′. In this embodiment, the method to form the photovoltaic layer 230′, for example, can be Radio Frequency Plasma Enhanced Chemical Vapour Deposition (RF PECVD), Very High Frequency Plasma Enhanced Chemical Vapour Deposition (VHF PECVD) or Microwave Plasma Enhanced Chemical Vapour Deposition (MW PECVD).

After that, as shown in FIG. 10E, photovoltaic material layer M is patterned to form a plurality of openings H′, wherein the openings H′ are exposing the first conductive layer 220′ of the first photovoltaic cells 202′, respectively. In this embodiment, the method to form the number of openings H′ is, for example, using the laser cutting, etching or mechanical removal process.

And as shown in FIG. 10F, second conductive material layer C2′ is formed on the substrate 210′ to cover the photovoltaic material layer M′. In which the second conductive layer 240′ is generally used as the upper electrode of the photovoltaic cells 202′. In this embodiment, the method to form the second conductive layer 240′ is, for example, sputtering, chemical vapour deposition (CVD) or evaporation and the material can be the above mentioned transparent conductive material. The details are not iterated herein.

Hereafter, as shown in FIG. 10G, the second conductive material layer C2′ and the photovoltaic material layer M′ is patterned to form the second conductive layer 240′ and the photovoltaic layer 230′ of the first photovoltaic cell 202′. Wherein, the second conductive layer 240′ of each of the first photovoltaic cells 202′ is electrically connected to the first conductive layer 220′ of the adjacent first photovoltaic cell 202′ through the opening H′.

In this embodiment, it has to be specified that in the process of patterning which is mentioned in FIG. 12G, laser process, etching or mechanical removal process can be used to separate the second photovoltaic cells 204′ and the first photovoltaic cells 202′. This means that the first photovoltaic cells 202′ and the second photovoltaic cells 204′ are formed on the substrate 210′ simultaneously, in this embodiment.

Next, the magnitude of photocurrents generated by the first photovoltaic cells 202′ is detected. In this embodiment, the method of detecting the magnitude of photocurrent is illuminating a uniform light to each of the first photovoltaic cells 202′ and detecting with the photocurrent detecting device. The above description is provided only for illustration purposes. In other possible embodiment, persons skilled in the art can use any other appropriate detecting methods to detect the photocurrent. The details are not iterated herein.

After that, the second photovoltaic cell 204′ is electrically connected to one of the first photovoltaic cells 202′ in order to obtain current matching of the photocurrents generated by the overall first photovoltaic cells 202′. Wherein, the implementation method of electrically connection is illustrated in the following, but the present invention is not limited thereto.

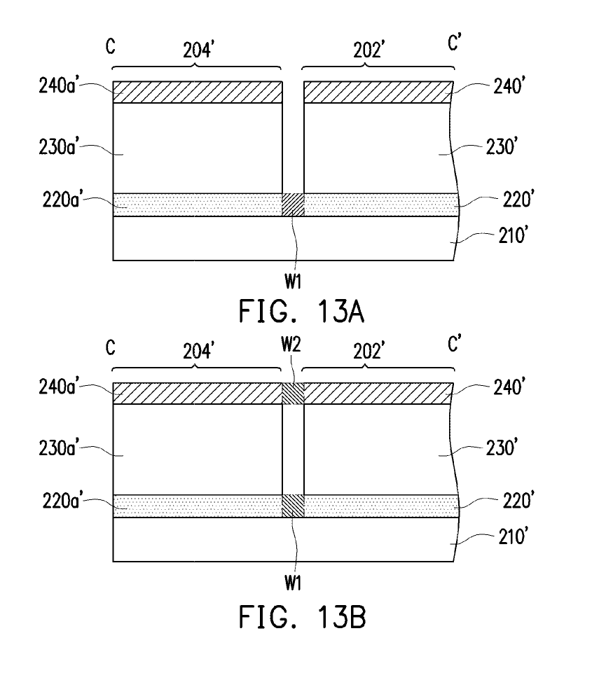

FIGS. 13A and 13B schematically illustrate a method of electrically connecting between the first photovoltaic cell and the second photovoltaic cell according to an embodiment of the present invention.

First, referring to FIG. 13A, the first conductive layer 220a′ of the second photovoltaic cell 204′ is electrically connected to the first conductive layer 220′ of the first photovoltaic cell 202′ which generates the smaller photocurrent with laser welding process, and it is illustrated as the welding zone W1′ in the figure. Then, referring to FIG. 13B, the second conductive layer 240′ of the second photovoltaic cell 204′ is electrically connected to the second conductive layer 240a′ of the first photovoltaic cell 202′ which generates the smaller photocurrent with laser welding process, and it is illustrated as the welding zone W2′ in the figure. At this point, the manufacturing process of the above mentioned thin film solar cell 200′ illustrated in FIG. 5 is completed.

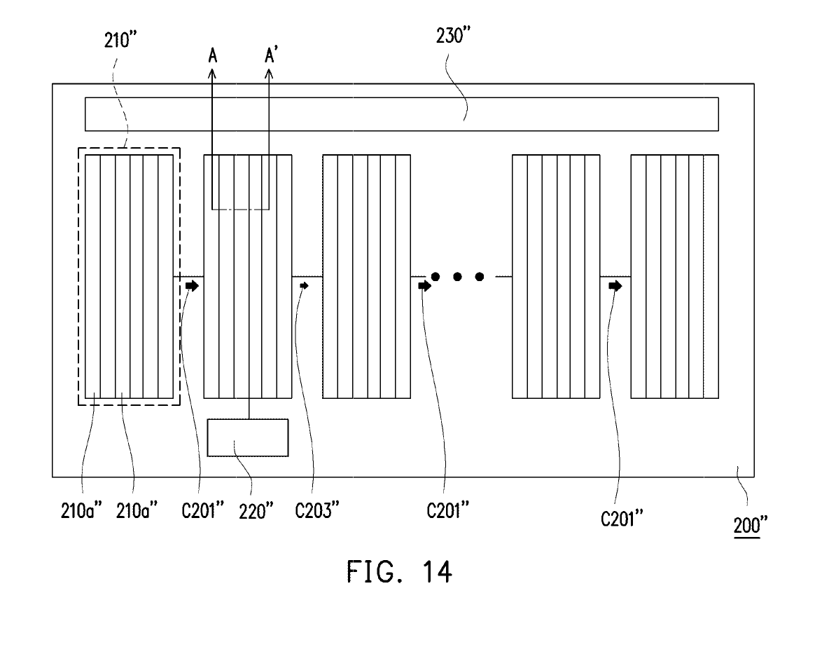

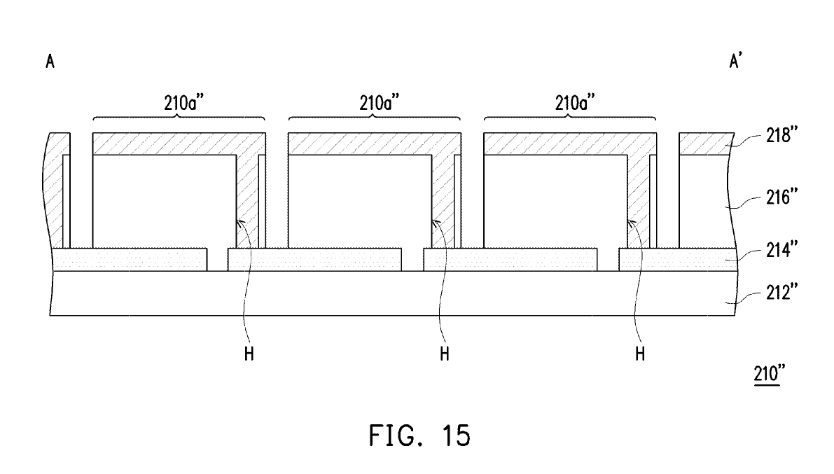

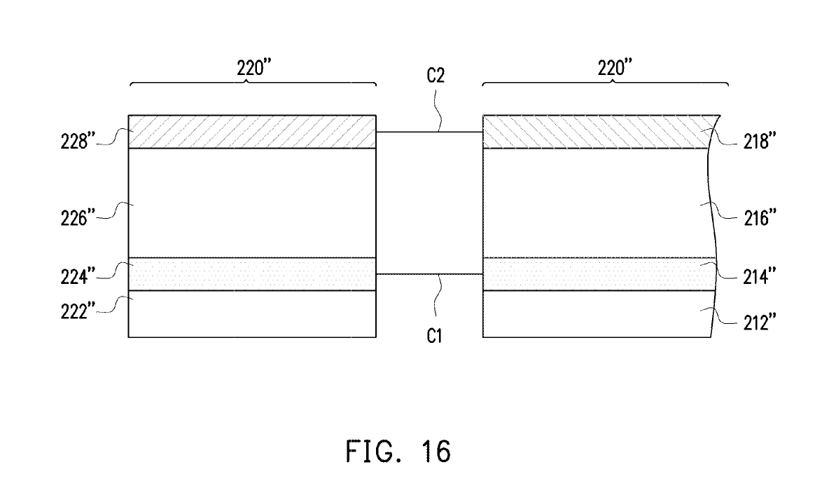

FIG. 14 schematically illustrates a thin film solar cell system according to an embodiment of the present invention. FIG. 15 schematically illustrates a cross-sectional view of a thin film solar cell of FIG. 14 along the A-A′ line. FIG. 16 schematically illustrates an embodiment of the electrically connecting of the first photovoltaic cell and the second photovoltaic cell.

Referring to FIG. 14 and FIG. 15, the thin film solar cell system 200″ includes a plurality of thin film solar cell modules 210″ and a current matching module 220″. In which the number of current matching modules 220″ is illustrated one as an example. The number of current matching modules 220″ depends on the users' requirement and is not limited in the thin film solar cell system 200″ in the present invention.

The thin film solar cell modules 210″ are connected in electrical series with one another and each providing a photocurrent respectively. Each of the thin film solar cell modules 210″ at least includes a substrate 212″, a first conductive layer 214″, a photovoltaic layer 216″ and a second conductive layer 218″. In this embodiment, the substrate 212″ can be a transparent substrate, for example, a glass substrate. The first conductive layer 214″ is disposed on the substrate 212″. The photovoltaic layer 216″ is disposed on the first conductive layer 214″. The second conductive layer 218″ is disposed on the photovoltaic layer 216″.

In this embodiment, each of the thin film solar cell 200″ is composed with a plurality of thin film solar cells 210a″ electrically connecting in series with each other. This means that the second conductive layer 218″ of each of the thin film solar cells 210a″ is electrically connected to the first conductive layer 214″ of the adjacent thin film solar cell 210a″ through the opening H″ as shown in FIG. 15. It is worth mentioning that the number of thin film solar cells 210a″ of each of thin film solar cell system 210″ is not limited in present invention. This means that in other possible embodiment, the thin film solar cell system 210″ can include a single thin film solar cell 210a″.

In this embodiment, the first conductive layer 214″ is a transparent conductive layer, for example, and the material thereof can be at least one of the zinc oxide, indium tin oxide (ITO), indium zinc oxide (IZO), indium tin zinc oxide (ITZO), aluminium tin oxide (ATO), aluminium zinc oxide (AZO), cadmium indium oxide (CIO), cadmium zinc oxide (CZO), gallium zinc oxide (GZO) and fluorine tin oxide (FTO). In another embodiment (not shown), the first conductive layer 214″ can be a stacked layer of a reflective layer (not shown) and the above-mentioned transparent conductive layer, and the reflective layer is disposed between the transparent conductive layer and the substrate. The material of the reflective layer can be a metal with higher reflectivity, such as aluminium (Al), silver (Ag), molybdenum (Mo) or copper (Cu).

In this embodiment, the material of the photovoltaic layer 216″ can be a semiconductor thin film in Group IV elements of the Periodic Table, Group III-V compound semiconductor thin film, Group II-VI compound semiconductor thin film, organic semiconductor thin film or compound thereof. In details, the semiconductor thin film in Group IV elements of the Periodic Table is at least one of a carbon thin film, a silicon thin film, a germanium thin film, a silicon carbide thin film and a silicon germanium thin film, each of which may be in monocrystalline form, polycrystalline form, amorphous form or microcrystalline form, or a combination thereof. For example, the compound semiconductor thin film in Group III-V of the Periodic Table is at least one of gallium arsenide (GaAs) thin film and indium gallium phosphide (InGaP) thin film, or a combination thereof. The compound semiconductor thin film in Group II-VI, for example, includes at least one of a copper indium diselenide (CIS) thin film, a copper indium gallium diselenide (CIGS) thin film and a cadmium telluride (CdTe) thin film, or a combination thereof. Furthermore, the above mentioned organic compound semiconductor thin film can be a mixture of a conjugated polymer donor and PCBM acceptor.

In addition, the film structure of the above mentioned photovoltaic layer 216″ can be a PN single layer of photoelectric conversion structure composed of P-type semiconductor and N-type semiconductor or a PIN single layer of photoelectric conversion structure composed of P-type semiconductor, intrinsic layer and N-type semiconductor. However, the present invention is not limited thereto. In another embodiment, the film structure of the photovoltaic layer 216″ can be a stacked structure of a tandem junction, a triple junction or more than three-layers of photoelectric conversion film structure.

In this embodiment, the material of the above-mentioned transparent conductive layer can be used in the second conductive layer 218″, and the details are not iterated herein. In this embodiment, the second conductive layer 218″ can further include a reflective layer disposed on the transparent conductive layer. It is noted that when the second conductive layer 218″ includes a reflective layer, the first conductive layer 214″ can only be a transparent conductive layer. On the contrary, when the first conductive layer 218″ includes a reflective layer, the second conductive layer 218″ can only be a transparent conductive layer without a reflective layer thereon. In an embodiment, each of the first conductive layer 214″ and the second conductive layer 218″ can be a single transparent conductive layer without a reflective layer thereon. In other words, the design of the first conductive layer 214″ and the second conductive layer 218″ can be adjusted according to the users' requirements (e.g. for manufacturing a thin film solar cell with double-sided illumination or a thin film solar cell with one-sided illumination). The design of the first conductive layer 214″ and the second conductive layer 218″ described above is provided only for illustration purposes, and is not construed as limiting the present invention.

Referring to FIG. 14 and FIG. 15, the current matching module 220″ is a thin film solar cell, for example, and includes a substrate 222″, a first conductive layer 224″, a photovoltaic layer 226″ and a second conductive layer 228″. The first conductive layer 224″ is disposed on the substrate 222″ of the current matching module 220″. The photovoltaic layer 226″ is disposed on the first conductive layer 224″ of the current matching module 220″. The second conductive layer 228″ is disposed on the photovoltaic layer 226″ of the current matching module 220″. The material used in the substrate 222″, the first conductive layer 224″, the photovoltaic layer 226″ and the second conductive layer 228″ is generally the same with the above mentioned substrate 212″, first conductive layer 214″, photovoltaic layer 216″ and second conductive layer 218″. The details are not iterated herein.

In this embodiment, the disposing of current matching module 220″ can improve the overall current output efficiency of the thin film solar cell system 200″. For example, when the photocurrent C203″ provided by at least one of the thin film solar cell modules 210″ is different from the photocurrents C201″ provided by the other thin film solar cell modules 210″, the current matching module 220″ can be electrically connected to the thin film solar cell module 210″ which generates smaller photocurrents in order to obtain current matching of the photocurrents provided by the thin film solar cell modules 210″ (i.e., to make the photocurrent C203″ and the photocurrent C201″ equal). In this way, the overall current output efficiency of the thin film solar cell system 200″ can be improved.

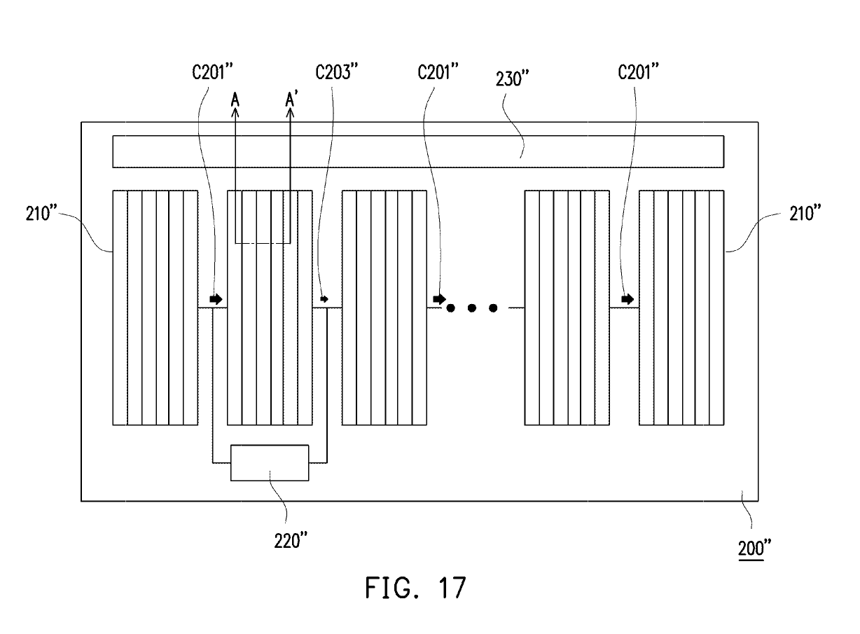

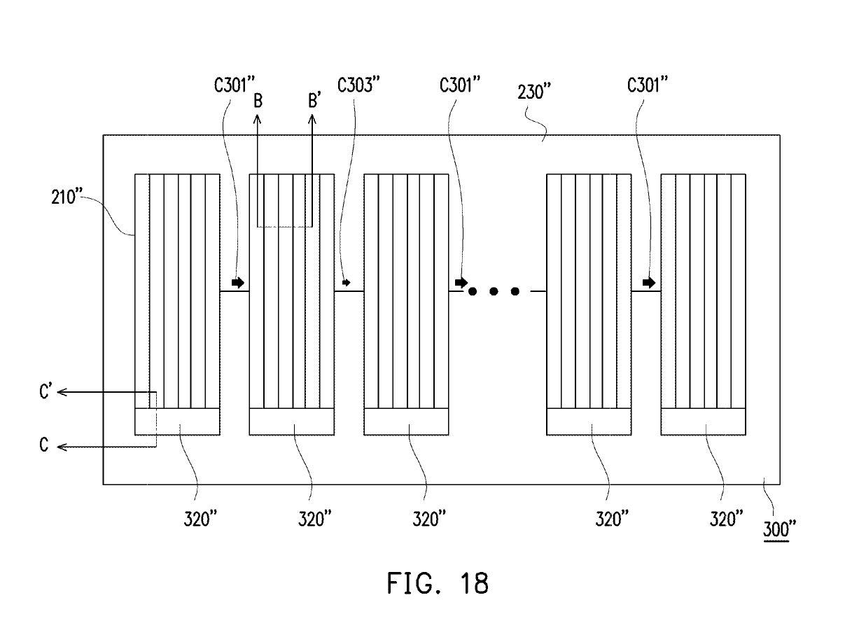

The following illustrates an example of the method of electrically connecting in parallel between the above current matching module 220″ and the thin film solar cell module 210″. The first conductive layer 224″ of the current matching module 220″ is electrically connected to the first conductive layer 214″ of the thin film solar cell module 210″ through a cable C1″. And the second conductive layer 228″ of the current matching module 220″ is electrically connected to the second conductive layer 218″ of the thin film solar cell module 210″ through another cable C1″ as shown in FIG. 16. In an embodiment, the current matching module 220″, for example, is electrically connected to one of the thin film solar cells 210a″ of the thin film solar cell module 240″. Or in another embodiment, the current matching module 220″ can also be electrically connected in parallel with the whole thin film solar cell module 210″ as illustrated in FIG. 17.

Referring to FIG. 14, in this embodiment, a photocurrent detecting device 230″ can be selectively disposed in the thin film solar cell system 200″ to detect the photocurrent generated by each of the thin film solar cell modules 210″. In which the photocurrent detecting device 230″ can be any other appropriate detecting device which is chosen by person skilled in the art and the details are not iterated herein. However, the disposing of photocurrent detecting device 230″ is not essential. In other embodiment, the thin film solar cell system can be without a photocurrent detecting device.

In addition, in another embodiment, the above mentioned current matching module 220″ can be an external power supply unit. The current matching module 220″ is electrically connected in parallel to at least one of the thin film solar cell modules 210″ in order to obtain current matching of the photocurrents provided by the thin film solar cell modules 210″ (i.e., to make the photocurrent C203″ and the photocurrent C201″ equal). This means that it is not limited in present invention that the current matching module 220″ is the above mentioned thin film solar cell. For example, when the current matching module 220″ is an external power supply unit, only an external electric current is needed to provide to one of the thin film solar cell modules 210″ which generates smaller photocurrent C203″ in order to make the photocurrents of overall thin film solar cell modules 210 current matching (i.e., to make the photocurrent C203″ and the photocurrent C201″ equal). In this way, the whole current output efficiency of the thin film solar cell system 200″ can be improved.

Since the thin film solar cell system 200″ includes the above mentioned current matching module 220″, when the photocurrents provided by the thin film solar cell modules 210″ are different from each other, the current matching modules 220″ can provide the current matching of the photocurrents of the thin film solar cell modules 210″ to improve the current output and thus the whole photoelectric conversion efficiency is ameliorated.

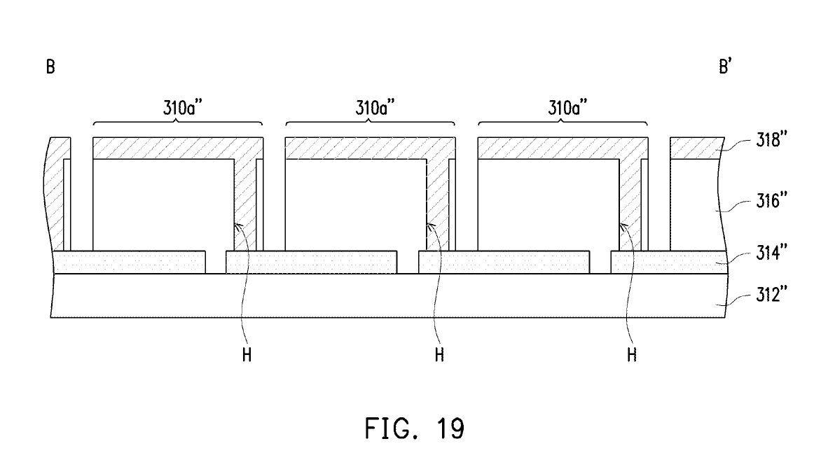

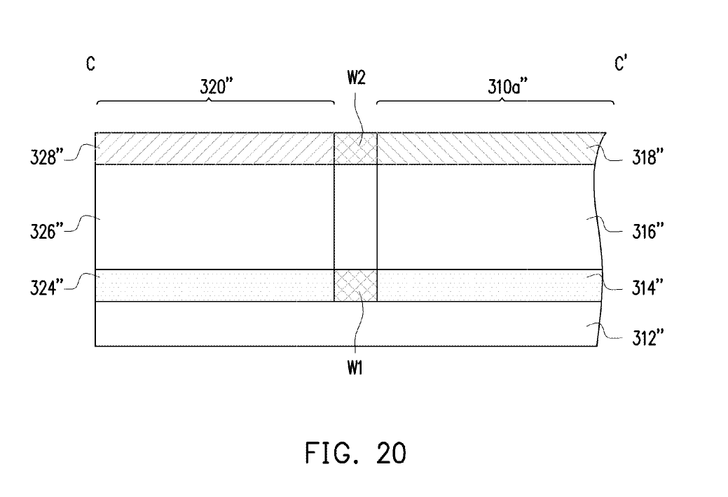

FIG. 18 schematically illustrates a top view of a thin film solar cell system according to an embodiment of the present invention. FIG. 19 schematically illustrates a cross-sectional view of a thin film solar cell module of FIG. 18 along the B-B′ line. FIG. 20 schematically illustrates a cross-sectional view of FIG. 18 along the C-C′ line, an embodiment of wherein the first photovoltaic cell and the second photovoltaic cell are electrically connected.

Referring to FIG. 18 and FIG. 19, the thin film solar cell system 300″ includes a plurality of thin film solar cell modules 310″. The thin film solar cell modules 310″ are connected in electrical series with one another and each providing a photocurrent respectively. Each of the thin film solar cell modules 310″ at least includes a substrate 312″, a plurality of first photovoltaic cells 310a″ and at least a second photovoltaic cell 320″. In this embodiment, the substrate 312″ is a transparent substrate, for example, a glass substrate.

The first photovoltaic cells 310a″ are disposed on the substrate 312″. Each of the first photovoltaic cells 310a″ includes a first conductive layer 314″, a photovoltaic layer 316″ and a second conductive layer 318″. The first conductive layer 314″ is disposed on the substrate 312″. The photovoltaic layer 316″ is disposed on the first conductive layer 314″. The second conductive layer 318″ is disposed on the photovoltaic layer 316″. In which each of the second conductive layer 318″ of the first photovoltaic cells 310a″ is electrically connected to the first conductive layer 314″ of the adjacent first photovoltaic cell 310a″ through the opening H″ in order to let the first photovoltaic cells 310a″ be connected in series to each other. The material used in the first conductive layer 314″, the photovoltaic layer 316″ and the second conductive layer 318″ is generally the same with the above mentioned embodiment of first conductive layer 214″, photovoltaic layer 216″ and second conductive layer 218″. The details are not iterated herein.

Referring to FIG. 20, the second photovoltaic cell 320″ is disposed on the substrate 312″. In this embodiment, each of the second photovoltaic cells 320″ includes a first conductive layer 324″, a photovoltaic layer 326″ and a second conductive layer 328″. The first conductive layer 324″ is disposed on the substrate 312″. The photovoltaic layer 326″ is disposed on the first conductive layer 324″. The second conductive layer 328″ is disposed on the photovoltaic layer 326″. Similarly, the material used in the first conductive layer 324″, the photovoltaic layer 326″ and the second conductive layer 328″ is generally the same with the above mentioned embodiment of first conductive layer 214″, photovoltaic layer 216″ and second conductive layer 218″. The details are not iterated herein.

In the thin film solar cell system 300″, when the photocurrents C303″ generated by at least one of the thin film solar cell modules 310″ are different from the photocurrents C301″ generated by other thin film solar cell modules 310″, the second photovoltaic cell 320″ of the thin film solar cell module 310″ can be electrically connected in parallel to at least a part of the first photovoltaic cell 310a″ in order to obtain the current matching of the photocurrents generated by the overall thin film solar cell modules 310″ (i.e., to make the photocurrent C203″ and the photocurrent C201″ equal). In which when the second photovoltaic cell 320″ is electrically connected to at least a part of the first photovoltaic cell 310a″, the first conductive layer 324″ of the second photovoltaic cell 320″ can be electrically connected to the first conductive layer 314″ of the first photovoltaic cells 310a″ through the welding zone W1″, for example, and the second conductive layer 328″ of the second photovoltaic cell 320″ can be electrically connected to the second conductive layer 318″ of the first photovoltaic cells 310a″ through the welding zone W2″.

In another embodiment (not shown), when the photocurrents generated by first photovoltaic cells 310a″ are in good current matching conditions, the second photovoltaic cells 320″ can be electrically connected in series to first photovoltaic cells 310a″. Otherwise, the second photovoltaic cells 320″ can be divided into a plurality of subunits. Each of the subunits can be electrically connected in parallel to the first photovoltaic cells 310a″ respectively in order to make full use of the second photovoltaic cells 320″ to generate photocurrents. In this way, the areas of the second photovoltaic cells 320″ being occupied in the thin film solar cell modules 310″ will not be wasted.

In summary, the thin film solar cell of the present invention is designed with the control unit. Thus, when the photocurrents provided by the photovoltaic cells are different, the control unit can be electrically connected to the part of the first photovoltaic cells in order to improve the current matching of the photocurrents which are in series. In other words, the thin film solar cell of an embodiment of present invention has a better photoelectric conversion efficiency. Besides, the manufacturing and optimization method of the thin film solar cell of an embodiment of present invention can form the above mentioned control unit under the condition of without increasing the manufacturing process. Thus, the performance of the thin film solar cell can be improved in a simple way.

Since the thin film solar cell of the present invention is designed with a second photovoltaic cell, when the photocurrents provided by the first photovoltaic cells are different, the second photovoltaic cell can be electrically connected to a part of the first photovoltaic cells in order to improve the current matching of the photocurrents which are in series. In other words, the thin film solar cell of an embodiment of present invention has a better photoelectric conversion efficiency. Besides, the manufacturing method of the thin film solar cell of an embodiment of present invention can form the above mentioned second photovoltaic cell under the condition of without increasing the manufacturing process. Thus, the performance of the thin film solar cell can be improved in a simple way.

Since the thin film solar cell system of the present invention is designed with a current matching module, when the photocurrents provided by the current matching modules are different, the current matching module can be electrically connected to a part of the thin film solar cell modules in order to improve the current matching and the current output of the photocurrents which are in series. In other words, the thin film solar cell system of an embodiment of present invention has a better photoelectric conversion efficiency. In an embodiment, since the thin film solar cell system of the present invention is designed with a second photovoltaic cell, when the photocurrents provided by the thin film solar cell modules are different, the second photovoltaic cell can be electrically connected to a part of the first photovoltaic cells in order to improve the current matching of the photocurrents which are in series.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

1. A thin film solar cell, comprising:
a substrate;
a plurality of photovoltaic cells, disposed on the substrate, generate a photocurrent respectively, wherein each photovoltaic cell comprising:
a first conductive layer, disposed on the substrate;
a photovoltaic layer, disposed on the first conductive layer and having an opening exposing the first conductive layer;
a second conductive layer, disposed on the photovoltaic layer through the opening and electrically connected to the first conductive layer of the adjacent photovoltaic cell; and
at least one control unit, electrically connected to the photovoltaic cells, wherein when the control unit examines the photocurrents generated by at least one of the photovoltaic cells are different from the photocurrents generated by other photovoltaic cells, the control unit provides a compensable current to the photovoltaic cells in order to obtain current matching of the photocurrents generated by the overall photovoltaic cells.

2. The thin film solar cell of claim 1, wherein the control unit is an Application-Specific Integrated Circuit (ASIC).

3. The thin film solar cell of claim 1, wherein when the control unit provides the compensable current to the photovoltaic cells, the electrodes of the control unit is electrically connected to the first conductive layer and the second conductive layer of the photovoltaic cells respectively.

4. The thin film solar cell of claim 1, wherein a conducting wire or a bonding wire method is used in the electrically connecting between the control unit and the photovoltaic cells.

5. The thin film solar cell of claim 1, wherein the control unit is integrated into the layers of the photovoltaic cells.

6. The thin film solar cell of claim 1, wherein when the control units are more than two, the control units are placed at the same side or different side of the photovoltaic cells.

7. A thin film solar cell, comprising:
a substrate;
a plurality of first photovoltaic cells, disposed on the substrate, generate a photocurrent respectively, wherein each of the first photovoltaic cells comprising:
a first conductive layer, disposed on the substrate;
a photovoltaic layer, disposed on the first conductive layer and having an opening exposing the first conductive layer;
a second conductive layer, disposed on the photovoltaic layer through the opening and electrically connected to the first conductive layer of the adjacent first photovoltaic cell; and
at least one second photovoltaic cell, disposed on the substrate, wherein when the photocurrents generated by first photovoltaic cells are different, the second photovoltaic cell is electrically connected to at least a part of the first photovoltaic cells in order to obtain current matching of the photocurrents generated by the overall photovoltaic cells.

8. The thin film solar cell of claim 7, wherein the expansion direction of at least a second photovoltaic cell is perpendicular to the first photovoltaic cells thereof.

9. The thin film solar cell of claim 7, wherein each of the second photovoltaic cell comprising:
a first conductive layer, disposed on the substrate;
a photovoltaic layer, disposed on the first conductive layer; and
a second conductive layer, disposed on the photovoltaic layer, wherein when the second photovoltaic cell is electrically connected to at least a part of first photovoltaic cells, the first conductive layer of the second photovoltaic cell and the first conductive layer of the first photovoltaic cells is electrically connected, and the second conductive layer of the second photovoltaic cells and the second conductive layer of the first photovoltaic cells are electrically connected.

10. The thin film solar cell of claim 7, wherein the number of the second photovoltaic cells is at least more than two.

11. The thin film solar cell of claim 10, wherein each of the second photovoltaic cells includes a photovoltaic zone, and the areas of the photovoltaic zones of the second photovoltaic cells are of the same or different.

12. The thin film solar cell of claim 10, wherein the second photovoltaic cells are placed at the same or different side of the first photovoltaic cells.

13-17. (canceled)

18. A thin film solar cell system including a plurality of thin film solar cell modules, being in electrical series with one another and providing a photocurrent respectively, wherein each of the thin film solar cell modules, at least comprising:
a substrate;
a plurality of first photovoltaic cells, disposed on the substrate, and each of the first photovoltaic cells comprising:
a first conductive layer, disposed on the substrate;
a photovoltaic layer, disposed on the first conductive layer;
a second conductive layer, disposed on the photovoltaic layer; and
at least a second photovoltaic cell, disposed on the substrate, wherein when the photocurrent provided by at least one of the thin film solar cell modules is different from the photocurrents provided by the other thin film solar cell modules, the second photovoltaic cell of the thin film solar cell module is electrically connected in parallel to at least a part of the first photovoltaic cells of the thin film solar cell modules in order to obtain current matching of the photocurrents generated by the thin film solar cell modules.

19. The thin film solar cell system of claim 18 further comprises a current detecting device to detect the photocurrent magnitude provided by each of the thin film solar cell modules.

20. The thin film solar cell system of claim 18, wherein each of the second photovoltaic cells comprising:
a first conductive layer, disposed on the substrate;
a photovoltaic layer, disposed on the first conductive layer; and
a second conductive layer, disposed on the photovoltaic layer,
wherein, when the second photovoltaic cell is electrically connected to at least a part of the first photovoltaic cells, the first conductive layer of the second photovoltaic cell and the first conductive layer of the first photovoltaic cells are electrically connected, and the second conductive layer of the second photovoltaic cell is electrically connected to the second conductive layer of the first photovoltaic cells.
